(19) United States
(12) Patent Application Publication
(10) Pub. No.: US 2021/0190473 A1
(43) Pub. Date: Jun. 24, 2021

(54) STATOR PACKAGE, ROTOR PACKAGE AND INDUCTIVE ANGLE SENSOR

(71) Applicant: Infineon Technologies AG, Neubiberg (DE)

(72) Inventor: Udo AUSSERLECHNER, Villach (AT)

(73) Assignee: Infineon Technologies AG, Neubiberg (DE)

(21) Appl. No.: 17/123,572

(22) Filed: Dec. 16, 2020

(30) Foreign Application Priority Data
Dec. 20, 2019 (DE) 102019220393.0

(51) Int. Cl. G01B 7/30; G01D 5/22

(52) U.S. Cl. CPC G01B 7/30; G01D 5/2216

(57) ABSTRACT

The present disclosure relates, inter alia, to a stator package for use in an inductive angle sensor, wherein the stator package includes a substrate, on which at least two metallization layers arranged at different levels are arranged. The stator package also includes a semiconductor chip with an integrated circuit, wherein an electrically insulating potting compound surrounds the substrate including the semiconductor chip and a receiving coil arrangement. The receiving coil arrangement includes at least two electrically conductive receiving coils, which are implemented in the two metallization layers by thin-film technology.

### FIELD

The present concept relates to a stator package for use in an inductive angle sensor and to an associated rotor package for use in an inductive angle sensor. The present concept also relates to an inductive angle sensor with such a rotor package and such a stator package and to corresponding methods for producing the packages and the inductive angle sensor.

### BACKGROUND

Position sensors are used to determine the position between two components rotating in relation to one another, such as for example a rotor and a stator. Such angle sensors are used for example for determining a steering angle or for determining the position of an engine shaft and the like.

There are various methods and devices for determining the angle between two components. The concept described here is concerned with sensors in the technical field of inductive angle measurement.

### SUMMARY

In the case of sensors which use the inductive measuring principle, an excitation coil is arranged on a first sensor component, for example on a stator. The excitation coil is excited by an alternating current and then generates a corresponding induction field or magnetic field. A second sensor component, for example a rotor, is rotatable in relation to the first sensor component. A so-called inductive target is provided on the second sensor component. This inductive target receives the induction field or magnetic field generated by the excitation coil. The inductive target is electrically conductive, so that an induction current forms in the inductive target in response to the received induction field or magnetic field. This induced induction current in turn causes a corresponding induction field or magnetic field in the target. The first sensor component, that is to say for example the stator, has a receiving coil, which receives the induction field or magnetic field generated by the target and in response to this generates an induction signal, for example a corresponding induction current or an induction voltage. The signal strength of this induction signal in this case depends primarily on the position of the two sensor components in relation to one another, and consequently varies in dependence on the position of the two sensor components in relation to one another. Consequently, on the basis of an evaluation of the signal strength of the induction signal induced in the receiving coil, the position of the two sensor components in relation to one another can be determined.

This inductive sensor principle consequently differs from conventional magnetic field sensors, which measure the magnetic field strength of a magnetic field, in particular a permanent magnetic field. In this case, the magnetic field strength varies in dependence on the position of the two sensor components in relation to one another. Another difference is for example in the selection of the materials. While in the case of a magnetic field sensor ferromagnetic materials are used, in the case of inductive sensors non-ferromagnetic materials with electrical conductivity, for example aluminum, can also be used.

Magnetic field sensors can be produced with very small dimensions. However, magnetic field sensors are susceptible to the effect of external disturbances, which may result in particular from the presence of ferromagnetic materials. Consequently, the reliability of magnetic field sensors can vary, sometimes greatly, in environments with many magnetic components.

By contrast, inductive angle and/or position sensors are insensitive to ferromagnetic materials. The area of use of inductive sensors is consequently significantly extended in comparison with the area of use of previously described magnetic field sensors. Furthermore, inductive sensors are essentially unsusceptible to external influences, such as for example dust, dirt or liquids.

Depending on how sensitive the inductive sensor is intended to be, or how great the desired measuring distances of the inductive sensor are, sometimes high currents are induced in the respective coils. In order to ensure the desired high sensitivity of an inductive sensor, the losses and parasitic inductances should in this case be kept as low as possible. Accordingly, the dimensions of the windings of the respective coils should be designed for the sometimes high currents. The coils are therefore usually produced in the form of structured conductor tracks on printed boards, known as PCBs (PCB: Printed Circuit Board). Additionally arranged laterally alongside the structured conductor track coils on the PCB is a chip package with a corresponding circuit for operating the inductive sensor on the PCB. It is desirable for such inductive sensors to be as small as possible. However, both the structured conductor track coil on the PCB and the chip package placed alongside it require a certain minimum mounting area. Moreover, the minimum conductor track thickness that can be realized on a PCB is also an additional limiting factor in the degree of miniaturization of the sensor.

The coils on the PCB should in principle be produced very exactly, even small deviations from the desired layout potentially leading to errors in the angle measurement. For example, individual coils may be connected to one another by means of vias in the PCB. These vias may be arranged along the outer circumference and along the inner circumference of the coils. However, deviations in the arrangement and size of the vias may lead to errors of a higher order (in the angle domain), it being very difficult in turn to be able to compensate for these errors. The diameters of such vias in a PCB are also usually much greater than the width of individual conductor tracks on the PCB. Thus, for example, in the case of a coil with an inside diameter of 15 mm, the vias arranged on the inside diameter may be arranged so close together that for example there is no longer any space for a rotatable shaft required for the rotation, or a further reduction in size of the inside diameter is no longer possible. In addition to this there is the fact that the relatively high amount of metallization accounted for by all of the vias may lead to noticeable errors in the angle measurement, for example on account of undesired eddy currents in the vias or on account of capacitive coupling.

Inductive sensor systems with multiple components, for example with multiple coils, can be easily produced by PCB technology. For example, multilayer PCBs with multiple integrated metal layers may be used for this. However, an increase in the number of metal layers required for this leads to an increase in the production costs. As an alternative, the metal layers may be arranged on the front side and back side of a PCB, which is less expensive than the use of multilayer PCBs. However, this has the effect of increasing the vertical distance between the coils on the front side and the back side. This distance may be for example 0.5 mm, which corresponds to approximately 40% of the nominal air gap between the rotor and the stator, which in turn can have noticeable effects on the measuring accuracy. Furthermore, the restricted accuracy of the alignment of metal layers in the PCB can lead to angular errors.

Apart from this, PCBs may be susceptible to delamination on account of thermo-mechanical or hygro-mechanical stress, which may also lead to ruptures in the copper conductor tracks. It may therefore be necessary to test the coil integration in the field, for which purpose for example precise resistances may be used in the coil windings, it then being possible to check while operation is in progress whether these resistances are still present between various terminals. These resistances may take the form of SMD components, which are placed very precisely on the coil conductor tracks. Moreover, these SMD components have a height of 1 mm to 2 mm. This can also lead to angular errors, in particular in the case of small coils. Moreover, as a result there is a potential risk of collision between the rotor and the stator, which could damage the coils.

The production of inductive angle sensors or their individual components by PCB technology can therefore be easily carried out and is inexpensive, but with the increasing degree of miniaturization of the coils can lead to the aforementioned problems and to the associated measuring inaccuracies

It would accordingly be desirable to provide an inductive angle sensor or individual sensor components for such an inductive angle sensor that have the smallest possible dimensions but nevertheless produce precise measurement results and at the same time can be produced inexpensively.

Therefore, a stator package with the features of claim 1 is proposed as such a sensor component. Furthermore, a rotor package with the features of claim 16 is proposed as a further sensor component. Moreover, an angle sensor according to claim 17 with such a stator package and such a rotor package is proposed. Embodiments and further advantageous aspects of the respective devices are specified in the respectively dependent patent claims

According to one aspect, a stator package for use in an inductive angle sensor is proposed, wherein the stator package includes, inter alia, a substrate on which at least two metallization layers arranged at different levels may be arranged. The stator package may also include a receiving coil arrangement with at least two electrically conductive receiving coils, which are designed to receive a magnetic field emitted by an inductive target arrangement that is rotatable in relation to the stator package and to generate induction signals in response thereto. The stator package may also include a semiconductor chip, which is connected in an electrically conducting manner to the receiving coil arrangement, wherein the semiconductor chip includes an integrated circuit which is designed to evaluate the induction signals and to ascertain on the basis of the induction signals a rotation angle between the receiving coils and the inductive target arrangement rotatable in relation thereto. An electrically insulating potting compound may surround the substrate including the semiconductor chip and the receiving coils. According to the innovative concept described here, the two receiving coils may be implemented in the two metallization layers by thin-film technology.

According to a further aspect, a method for producing such a stator package is proposed, wherein the method includes, inter alia, a step of providing a substrate and arranging at least two metallization layers arranged at different levels on the substrate. The method may be devised in such a way as to produce a receiving coil arrangement with at least two electrically conductive receiving coils, which are designed to receive a magnetic field emitted by an inductive target arrangement that is rotatable in relation to the stator package and to generate induction signals in response thereto. A semiconductor chip may be arranged on or alongside the substrate and brought into electrical contact with the receiving coil arrangement, wherein the semiconductor chip may include a circuit which is designed to evaluate the induction signals and to ascertain on the basis of the induction signals a rotation angle between the receiving coils and the inductive target arrangement rotatable in relation thereto. The method may also be devised in such a way as to apply an electrically insulating potting compound, which surrounds the substrate including the semiconductor chip and the receiving coils. According to the innovative concept described here, the two receiving coils may be implemented in the two metallization layers by thin-film technology.

According to a further aspect, a rotor package for use in an inductive angle sensor is proposed, wherein the rotor package includes, inter alia, a substrate on which at least one metallization layer may be arranged. The rotor package may also include an inductive target arrangement with at least one electrically conductive inductive target, which is designed to generate an induction current in response to a magnetic field emitted by an excitation coil and to generate a magnetic field corresponding to the induction current and to emit it in the direction of the stator package. Furthermore, the rotor package may include an electrically insulating sealing or potting compound, which surrounds the substrate including the target arrangement. The rotor package may be arranged on a rotatable shaft for conjoint rotation and be rotatable in relation to the stator package. Furthermore, the at least one inductive target of the target arrangement may be implemented in the at least one metallization layer.

According to a further aspect, a method for producing such a rotor package is proposed, wherein the method includes, inter alia, a step of providing a substrate and arranging at least one metallization layer on the substrate. The method may be devised in such a way as to produce an inductive target arrangement with at least one electrically conductive inductive target, which is designed to generate an induction current in response to a magnetic field emitted by an excitation coil and to generate a magnetic field corresponding to the induction current and to emit it in the direction of the stator package. The at least one inductive target of the target arrangement may be implemented in the at least one metallization layer. In a further method step, an electrically insulating sealing or potting compound, which surrounds the substrate including the target arrangement, may be applied. Furthermore, the rotor package may be arranged on a rotatable shaft for conjoint rotation, so that the rotor package is rotatable in relation to the stator package.

### BRIEF DESCRIPTION OF THE DRAWINGS

Some exemplary embodiments are explained below and are represented by way of example in the drawing, in which:

FIG. 1 shows a lateral sectional view of an inductive angle sensor with a stator package and a rotor package according to an exemplary embodiment,

FIG. 2 shows a plan view of a stator package according to an exemplary embodiment,

FIG. 3A shows a lateral sectional view of an inductive angle sensor with a stator package and a rotor package according to a further exemplary embodiment,

FIG. 3B shows a lateral sectional view of an inductive angle sensor with a stator package and a rotor package according to a further exemplary embodiment,

FIG. 4 shows a lateral sectional view of an inductive angle sensor in an end-of-shaft configuration with a stator package, a rotor package and a separate component board according to an exemplary embodiment,

FIG. 5 shows a lateral sectional view of an inductive angle sensor in a through-shaft configuration with a stator package, a rotor package and a separate component board according to an exemplary embodiment,

FIG. 6 shows a schematic block diagram to illustrate a method for producing a stator package according to an exemplary embodiment, and

FIG. 7 shows a schematic block diagram to illustrate a method for producing a rotor package according to an exemplary embodiment.

### DETAILED DESCRIPTION

Exemplary embodiments are described in more detail below with reference to the figures, wherein elements with the same or a similar function are provided with the same reference signs.

Method steps that are shown in one block diagram and explained with reference to the same can also be carried out in a sequence other than that depicted or described. In addition, method steps that relate to a specific feature of a device can be exchanged with this very feature of the device, and the opposite is equally true.

The terms stator package and rotor package are used here mainly for better understanding. The two packages can rotate in relation to one another. Whether the rotor package rotates and the stator package is fixed in place, or whether perhaps the stator package rotates and the rotor package is fixed in place is immaterial here.

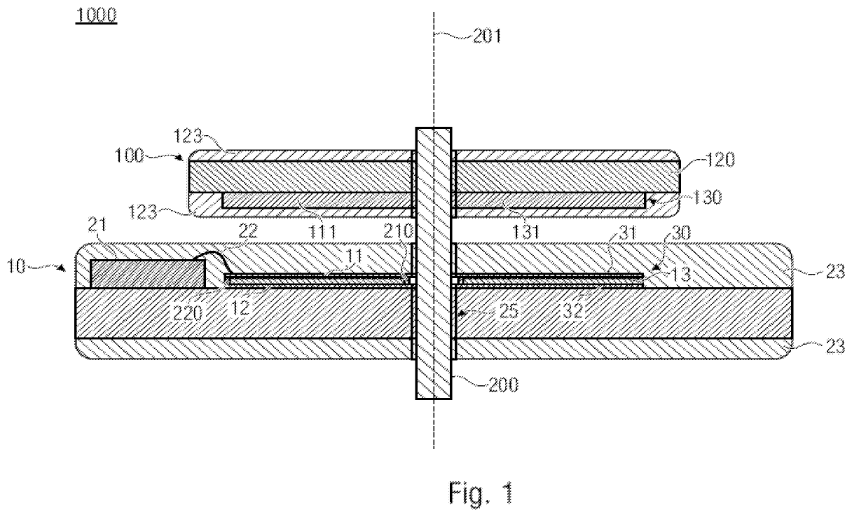

FIG. 1 shows an exemplary embodiment of an inductive angle sensor 1000 with a stator package 10 according to an embodiment that is given by way of example and is not limiting and also with a rotor package 100 according to an embodiment that is given by way of example and is not limiting.

The stator package 10 depicted here comprises a receiving coil arrangement 30 with at least two electrically conductive receiving coils 31, 32. The receiving coil arrangement 30 may however also comprise more than two electrically conductive receiving coils. Preferably, the receiving coil arrangement 30 may comprise an even number of receiving coils.

The rotor package 100, which is rotatable in relation to the stator package 10, comprises an inductive target arrangement 130. The inductive target arrangement 130 may comprise at least one electrically conductive inductive target 131. The inductive target arrangement 130 may however also comprise multiple electrically conductive inductive targets. For example, the inductive target arrangement 130 in the case of inductive angle sensors that use the vernier principle may comprise two electrically conductive inductive targets. The target arrangement 130 may however in principle also comprise more than two electrically conductive inductive targets. The number of electrically conductive inductive targets of the target arrangement 130 may for example be dependent on the number of receiving coils 31, 32 in the receiving coil arrangement 30. For example, an electrically conductive inductive target may be provided for every two receiving coils 31, 32.

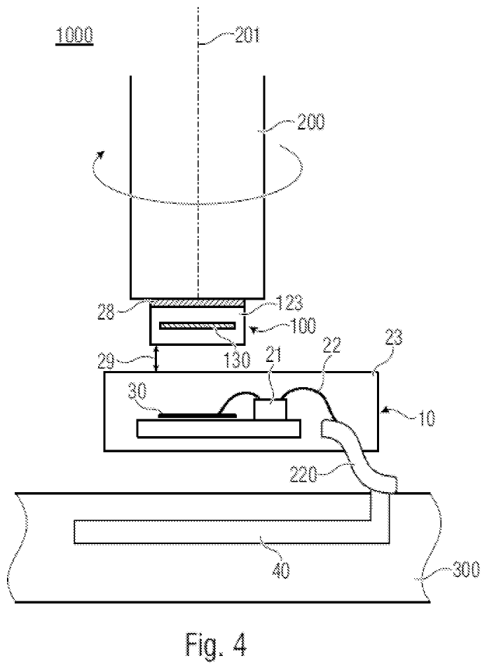

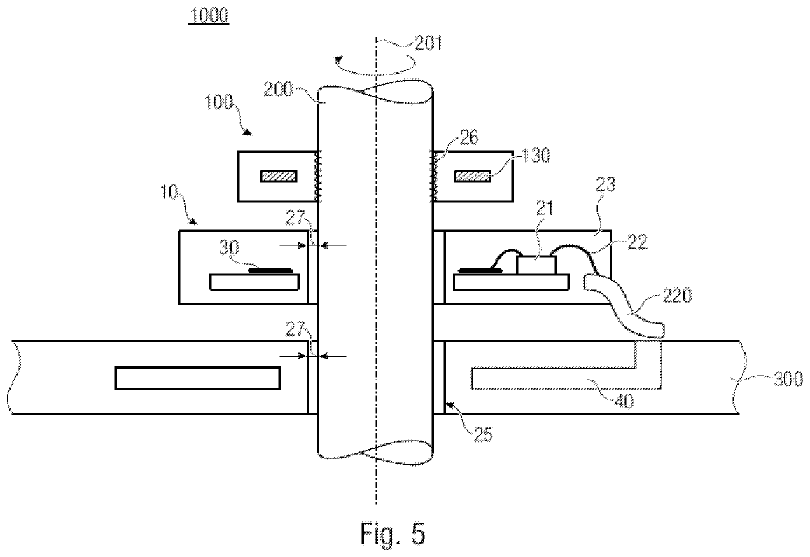

An excitation coil (not depicted here), which may for example be arranged in the stator package 10 or on an additional component board (see FIGS. 4 and 5), may emit a magnetic field in the direction of the inductive target 131. The inductive target 131 may be designed to generate an induction current in response to the magnetic field emitted by the excitation coil and to generate a magnetic field corresponding to the induction current, which is then in turn emitted in the direction of the stator package 10, and in particular in the direction of the receiving coil arrangement 30.

The receiving coils 31, 32 may be designed to receive the magnetic field emitted by the inductive target arrangement 131 that is rotatable in relation to the stator package 10 and to generate induction signals in response thereto. On the basis of these induction signals, the rotation angle between the stator package 10 and the rotor package 100 can be determined.

For this purpose, the stator package 10 may comprise a semiconductor chip 21. The semiconductor chip 21 may be connected in an electrically conducting manner, for example by means of bonding wires 22, to the receiving coil arrangement 30 and comprise an integrated circuit, for example an ASIC (Application Specific Integrated Circuit). The integrated circuit may be designed to evaluate the aforementioned induction signals, received from the receiving coil arrangement 30, and to ascertain on the basis of these induction signals the rotation angle between the receiving coil arrangement 30 that is arranged in the stator package 10 and the inductive target arrangement 130 that is rotatable in relation thereto and is arranged in the rotor package 100.

The stator package 10 may comprise a substrate 20. The substrate 20 may for example comprise at least one inorganic material from the group comprising silicon, glass or ceramic, or be produced therefrom. The substrate may have a thickness of between 50 μm and 800 μm, and preferably between 200 μm and 500 μm.

At least two metallization layers 11, 12 may be arranged on the substrate 20. At least one of the at least two metallization layers 11, 12 may also be, at least partially, integrated in the substrate 20. The metallization layers 11, 12 may be metal layers integrated in the substrate, for example inorganic substrates. It would likewise be conceivable that the substrate 20 is configured in the form of a WLB substrate or eWLB substrate ((e)WLB: (Embedded) Wafer Level Ball Grid Array). Here, the metallization layers 11, 12 may be for example in the so-called redistribution layer, RDL for short.

The at least two metallization layers 11, 12 may be arranged on two different levels. The cross section of the stack of layers may be such that the at least two metallization layers 11, 12 are provided on the base substrate 20. In other words, the stator package 10 may comprise a vertical stack of layers with at least two levels lying vertically one above the other, wherein at least one metallization layer 11, 12 is respectively arranged at each level. Consequently, the stack of layers comprises at least two metallization layers 11, 12 vertically spaced apart from one another. That is to say that the at least two metallization layers 11, 12 are not arranged laterally alongside one another but vertically one above the other.

According to the innovative concept described here, the at least two aforementioned receiving coils 31, 32 of the receiving coil arrangement 30 may be implemented in the aforementioned at least two metallization layers 11, 12 of the vertical stack of layers by thin-film technology.

For example, the at least two spaced-apart metallization layers 11, 12 may be structured by means of thin-film technology for producing the receiving coils 31, 32. The term thin-film technology may be understood as meaning structured metallization deposition (for example by means of sputtering or vapor depositing—with structuring by lithography). The term thin-film technology may likewise include when a thin so-called seed layer produced in this way is subsequently reinforced by a plating process—this may take place electrolytically or electrolessly. Dielectric layers may be produced or laminated by spin-on technology. Among the production methods that are used in thin-film technology are those known from microelectronics.

By contrast, the term thick-film technology would include for example subtractive techniques, such as for example in circuit board production (for example etching of copper-laminated layers) or else the printing of conductive pastes with subsequent curing. Structurally, metallization layers that have been produced by thin-film technology can consequently be distinguished from metallization layers produced by thick-film technology.

The advantages of thin-film technology lie in the possibility of realizing smaller structures (both structure widths and structure spacings). In the case of coils, for example, consequently more turns can be provided on the same surface area.

The application of thin-film technology described in the present disclosure in the production of inductive angle sensors accordingly allows the aforementioned receiving coils 31, 32 of the receiving coil arrangement 30 to be produced in a very miniaturized form, but nevertheless with very high accuracy. The entire stator package 10 can for example have a footprint (i.e. outer dimensions) of less than 15 mm, or of less than 10 mm.

According to an exemplary embodiment, the metallization layers 11, 12 may have in each case a layer thickness of 100 nm to 5 μm. Furthermore, the receiving coils 31, 32 of the receiving coil arrangement 30 that can be produced from the metallization layers 11, 12 by thin-film technology may comprise one or more turns with a width of 10 μm or less.

At least one electrically insulating layer 13 may be arranged between the at least two spaced-apart metallization layers 11, 12. On account of the thin-film technology that can be applied, there may also be the advantage here that this electrically insulating layer 13 can be very thin. The electrically insulating layer 13 may for example have a layer thickness of approximately 100 nm to approximately 10 μm, preferably of approximately 300 nm. This may be conducive to the matching, that is to say the pairing tolerance, of the two receiving coils 31, 32.

According to the innovative concept described here, the stator package 10 may also comprise an electrically insulating sealing or potting compound 23. The potting compound 23 may surround the substrate 20 including the semiconductor chip 21 and the receiving coils 31, 32. This offers a further decisive advantage. By means of the potting compound 23, the numerous connections (for example bonding wires 22) between the receiving coils 31, 32 and the semiconductor chip 21, or the integrated circuit, can be encapsulated. The entire stator package 10 can consequently be of a much more reliable and robust configuration than in the prior art. In the case of conventional angle sensors according to the prior art, soldered conductor tracks are provided on a printed board. These conductor tracks can become detached and they have a tendency to corrode. Furthermore, there is the risk of so-called cold solder joints. Printed boards also have a tendency for the individual layers to delaminate on account of thermal or mechanical stress.

In comparison, the fully encapsulated stator package 10 described here has significant advantages. The individual elements of the stator package 10 are to the greatest extent protected from external influences by the potting compound 23. In combination with the application of thin-film technology for producing the individual receiving coils 31, 32 of the receiving coil arrangement 30, it is consequently possible to produce a very miniaturized, high-precision and robust stator package 10, which moreover can be produced inexpensively.

The same also applies incidentally to the rotor package 100 described here. The rotor package 10 may also comprise a substrate 120, on or in which at least one metallization layer 111 may be arranged. Here, too, the substrate 120 may for example comprise at least one inorganic material from the group comprising silicon, glass or ceramic or be produced therefrom. The substrate 120 may have a thickness of between 50 μm and 800 μm, and preferably between 200 μm and 500 μm.

The rotor package 100 can also be produced in a miniaturized form. The entire rotor package 100 can for example have a footprint (i.e. outer dimensions) of less than 15 mm, or of less than 10 mm, or even of less than 5 mm. In one embodiment, the rotor package 100 may have outer dimensions of approximately 5×5 mm. The rotor package 100 may be designed as ring-shaped or round or oval. The rotor package 100 may in this case have a diameter of approximately 6 mm to 12 mm.

The previously mentioned inductive target arrangement 130 may be implemented in the at least one metallization layer 111. Here, too, thin-film technology may possibly be applied for producing the target arrangement 130. The target arrangement 130 may have the form of a coil or be designed in the form of a solid shaped metal part. For example, the target arrangement 130 may be produced from a thin metal sheet, for example a copper sheet. The target arrangement 130 may for example be stamped or etched from the metal sheet. In this case it is possible to dispense with the application of thin-film technology, so that a relatively thicker target arrangement 130, with a thickness of approximately 0.1 mm to 0.5 mm, may be produced. Such a target arrangement 130 would be more resistant to greater electrical currents.

This is relevant because the electrical induction currents occurring in the case of an inductive angle sensor 1000 may be much higher in the excitation coil and in the inductive target 130 than the currents induced in the receiving coils 31, 32 of the receiving coil arrangement 30. This is one reason why the receiving coils 31, 32 according to the concept described here can be produced particularly advantageously by thin-film technology.

As mentioned above, it is possible to dispense with the application of thin-film technology in the production of the target arrangement 130, in order to be able to conduct better the sometimes high electrical currents. For example, a metal sheet (for example a toothed disk or lead frame) may be preferred for the production of the target arrangement 130. For Vernier principles, for example, a target arrangement 130 with at least two inductive targets with different pole pitch is required (for example 3 and 4 teeth or loops of the turn). In such a case, on the other hand, it may be advantageous to use a substrate and to apply thicker metal layers to it, for example electrolytically. For example, first a thin layer may be applied by means of a sputtering technique, and then this layer can be made to become thicker, for example by electrolytic deposition.

In terms of the form, the target arrangement 130 may be designed as a coil, while it would then in turn be possible for example for it to be produced by means of thin-film technology. The geometrical form of the target arrangement 130 may for example be similar or identical to the geometrical form of the receiving coils 31, 32 of the receiving coil arrangement 30. In particular if the target arrangement 130 is designed as a coil, it would be an option to configure the substrate 120 in the form of a WLB substrate or eWLB substrate ((e)WLB: (Embedded) Wafer Level Ball Grid Array). Here, the metallization layer 111 from which the target arrangement 130 can be produced may be for example a metallization layer in the so-called redistribution layer, RDL for short.

The rotor package 100 may also be potted by means of a sealing or an electrically insulating potting compound 123. That is to say that the potting compound 123 may surround the substrate 120 including the metallization 111 or the inductive target arrangement 130 that can be produced therefrom. Consequently, the rotor package 100 can also be reliably protected from external influences. The rotor package 100 may in its outer appearance essentially resemble a pill.

Such a pill-shaped rotor package 100 may for example also be intentionally made somewhat thicker and have a thickness of approximately 5 mm. This could ensure a sufficiently great distance between the coils and a metallic rotatable shaft 200 in a so-called end-of-shaft system (see FIG. 4), or this could allow the coils to be arranged at right angles to the axis of rotation 201.

Such a rotatable shaft 200 is likewise shown in FIG. 1. The rotatable shaft 200 may rotate about its axis of rotation 201. The inductive angle sensor 1000 that is depicted here by way of example is a so-called through-shaft system. In this case, the rotatable shaft 200, seen in the running direction of its axis of rotation 201, runs rotatably through the entire stator package 10.

For example, for this purpose the stator package 10 may comprise a through-opening 25 extending through the substrate 20. The shaft 200 can then extend through this through-opening 25. Consequently, the shaft 200 can rotate independently of the stator package 10. Or in other words, the shaft 200 extending through the stator package 10 can rotate, while the stator package 10 remains stationary and does not rotate along with the shaft 200. The shaft 200 can in the same way also extend through the potting compound 23.

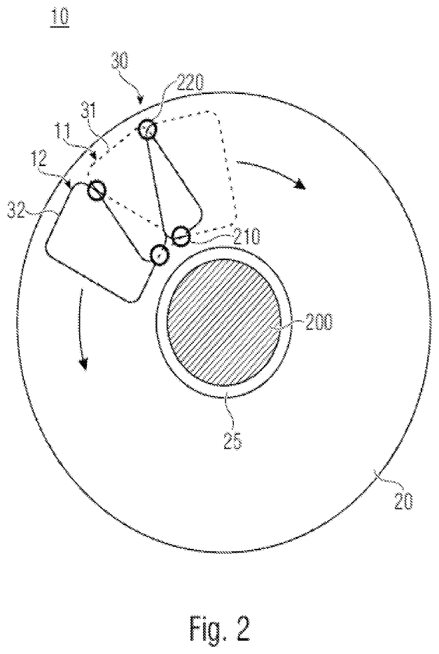

FIG. 2 shows schematically, and not to scale, a plan view of the stator package 10 with the shaft 200 running through. The shaft 200 extends through the through-opening 25 in the substrate 20. The through-opening 25 may for example have a diameter of between 2 mm and 5 mm. The shaft 200 may have a diameter that is slightly smaller, for example by a few tenths of a millimeter, so that it can be led rotatably through the through-opening 25. The shaft 200 may for example have a diameter of 1 mm to 4 mm.

Also shown in FIG. 2, likewise purely schematically and not to scale, is a detail of two metallization layers 11, 12, which are vertically spaced apart from one another and in which the receiving coils 31, 32 of the receiving coil arrangement 30 can be produced. The receiving coil arrangement 30 may be designed as ring-shaped and enclose or form a ring around the through-opening 25.

The different levels of the metallization layers 11, 12 are indicated here purely schematically by means of solid and dashed lines. This is intended to indicate that the individual receiving coils 31, 32 extend alternately over the two metallization layers 11, 12 or over the two levels, and are consequently woven within one another. That is to say that it should not necessarily be understood that the first receiving coil 31 is produced exclusively in a first metallization layer 11, and the second receiving coil 32 is produced exclusively in a second metallization layer 12. Rather, the two metallization layers 11, 12 may be used for producing both receiving coils 31, 32, wherein individual coil segments alternate between the first (upper) metallization layer 11 and the second (lower) metallization layer 12, so that the two receiving coils 31, 32 end up being woven within one another. That is to say that the wire of one coil 31 threads through a loop of the other coil 32, respectively. Thus, for example, also four coils may be produced in only two layers.

This alternation of the coil segments between the two levels of the metallization layers 11, 12 may for example take place in vertical plated-through holes or vias 210, 220 provided specifically for this purpose. That is to say that, in these vias 210, 220, the coil structure of a receiving coil 31, 32 changes between a first (upper) level and a second (lower) level. The two receiving coils 31, 32 cross one another as it were in these vias 210, 220, and change their respective level, so that there is no intersection of the receiving coils 31,32 with one another.

The vias 210, 220 may be arranged both at the outer circumference of the receiving coil arrangement 30 (see the vias 220) and at the inner circumference of the receiving coil arrangement 30 (see the vias 210). The production of the receiving coils 31, 32 by thin-film technology offers a further advantage here for the miniaturization of the stator package 10. This is so because the vias 210, 220 can likewise be produced by thin-film technology. The vias 210, 220 may have here a diameter of less than 10 μm. This offers the advantage that the vias 210 arranged at the inner circumference of the receiving coil arrangement 30 in particular can be arranged very close together. That is to say that the vias 210 need much less space in comparison with conventional vias in printed circuit boards as they have previously been configured in the prior art. Accordingly, the inside diameter of the receiving coil arrangement 30 described here, produced by thin-film technology, can be reduced significantly in comparison with conventional systems produced by PCB technology.

So the more the inside diameter of a receiving coil arrangement is reduced, the closer the vias distributed along the inside diameter move together. Vias in printed circuit boards have a diameter of 100 μm or more. That is to say that the more the inside diameter of a receiving coil arrangement is reduced in size, the more the individual vias distributed along the inside diameter are adjacent to one another and thereby restrict the reduction in size of the inside diameter of the receiving coil arrangement that is possible at all. Thus, for example, the inside diameter of a receiving coil arrangement that can be produced by PCB technology is restricted to approximately 15 mm. The outside diameter runs here to approximately 25 mm. In this case, the inside diameter of the receiving coil arrangement is populated with such a high density of vias that a further reduction in size is no longer possible, and there is also no space any longer for a rotatable shaft to be led through.

By contrast, the stator package 10 disclosed here, in which the receiving coils 31, 32 can be produced by thin-film technology, avoids this problem. As mentioned at the beginning, the vias 210, 220 can also be produced by thin-film technology with a diameter of approximately 10 μm or less. This allows the inside diameter of the receiving coil arrangement 30 to be reduced down to 5 mm, while nevertheless a shaft 200 still fits through the stator package 10. Also, the outside diameter can be reduced to approximately 16 mm or less, so that altogether a much smaller stator package 10 can be produced.

As shown by way of example in FIG. 2, the receiving coil arrangement 30 may be designed as ring-shaped and extend around the shaft 200. The vias 210 arranged at the inside diameter of the receiving coil arrangement 30 can accordingly likewise extend around the shaft 200 in a ring-shaped manner. Here the vias 210 can be brought very close to the through-opening 25.

The through-opening 25 may have a form that allows the shaft 200 (with a diameter of for example 1 mm to 5 mm) to be inserted through and still leave at least several tenths of a millimeter of air, in order to prevent direct contact and abrasion. The through-opening 25 may be circular, or else however square, oval or polygonal, for example triangular, rectangular, pentagonal, hexagonal, etc., perhaps with or without rounding of the corners. It is possible that such a through-opening 25 can be difficult to produce in some substrates, then resulting for example in one of the aforementioned special geometrical forms (for example a hexagon), which may deviate from a circular form shown here purely by way of example.

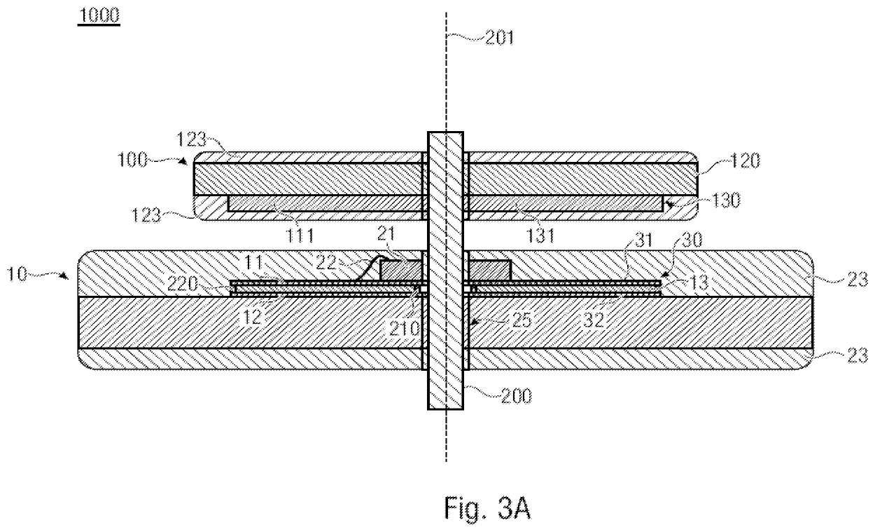

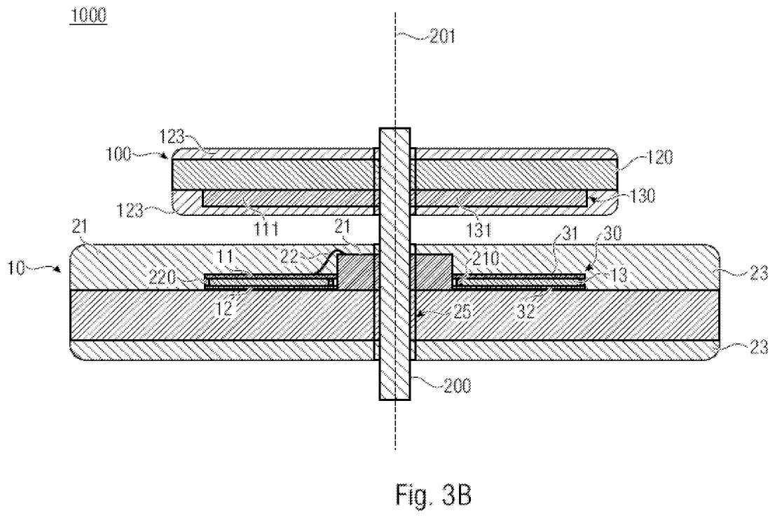

FIGS. 3A and 3B respectively show a further conceivable exemplary embodiment of an inductive angle sensor 1000. These embodiments are similar to the embodiment discussed above with reference to FIG. 1, for which reason elements with a similar or the same function are provided with the same reference signs. While in the exemplary embodiment shown in FIG. 1 the semiconductor chip 21 is arranged asymmetrically, i.e. laterally, in relation to the receiving coil arrangement 30, the semiconductor chip 21 in the case of the exemplary embodiments shown in FIGS. 3A and 3B may be arranged essentially centrally or in the middle.

FIG. 3A shows an exemplary embodiment in which the semiconductor chip 21 is arranged on the receiving coil arrangement 30. A dielectric layer (not shown here) may for example be provided between the semiconductor chip 21 and the receiving coil arrangement 30. The shaft 200 may extend through the semiconductor chip 21. That is to say that the semiconductor chip 21 may also have a through-opening 25, through which the shaft 200 extends. Seen in plan view, the receiving coil arrangement 30 would be arranged here, at least with its outside diameter, around the semiconductor chip 21. The semiconductor chip 21 may be arranged centrally with reference to the shaft 200 or the receiving coil arrangement 30.

FIG. 3B shows an alternative exemplary embodiment. Here, the inside diameter of the receiving coil arrangement 30 may be increased in size, so that the semiconductor chip 21 can be arranged within the receiving coil arrangement 30 on the substrate 20. Here, too, the shaft 200 can again extend through the semiconductor chip 21. Seen in plan view, the receiving coil arrangement 30 would be arranged here, both with its outside diameter and with its inside diameter, around the semiconductor chip 21. The semiconductor chip 21 may be arranged centrally with reference to the shaft 200 or the receiving coil arrangement 30.

As already mentioned at the beginning, the inductive angle sensors 1000 presented here may be so-called end-of-shaft systems or through-shaft systems. So far, through-shaft systems have been described purely by way of example.

FIG. 4 shows an example of an end-of-shaft system. In addition to the previously discussed embodiments, here an external component board 300 is shown. The component board 300 may be for example a PCB. An excitation coil 40 may be arranged in, at or on the component board 300. The excitation coil 40 may be connected in an electrically conductive manner to the semiconductor chip 21 or integrated circuit arranged in the stator package 10 by means of suitable galvanic connections, for example by means of bonding wires 220.

Alternatively, it would be conceivable that the excitation coil 40 is provided in the stator package 10. Here, the excitation coil 40 could be formed by thin-film technology in at least one of the at least two metallization layers 11, 12, or the excitation coil 40 could be formed by thin-film technology in at least one third metallization layer arranged on the substrate 20. In this case, the excitation coil 40 could also be potted in the potting compound 23 and connected in an electrically conducting manner to the semiconductor chip 21 and be able to be induced by an alternating current to generate a magnetic field.

As can be seen in FIG. 4, the stator package 10 may be arranged on the component board 300 and optionally fixed on it. For example, the stator package 10 may be bonded on the component board 300, adhesively attached or otherwise fastened on the component board 300. The stator package 10 itself may therefore be configured without a circuit board. Optionally, for example if the excitation coil 40 should be provided in the external component board 300, as shown in FIG. 4, the circuit board-less stator package 10 may be arranged on such an external circuit board (or component board) 300. Nevertheless, the stator package 10 itself would in this case be formed without a circuit board.

The stator package 10 may be immovable or non-rotatable. By contrast, the rotor package 100 may be movable or rotatable and rotate in relation to the non-rotatable stator package 10. For this purpose, the rotor package 100 may be arranged on an end portion of a rotatable shaft 200. For example, the rotor package 100 may be mounted on the end of the shaft 200 by means of an adhesive 28. The rotor package 100 can consequently rotate together with the rotatable shaft 200. In this case, the rotor package 100 and the stator package 10 may be spaced apart from one another, so that they cannot touch. That is to say that between the stator package 10 and the rotor package 100 there is an axial air gap 29, which prevents unwanted direct contact between the stator package 10 and the rotor package 100.

FIG. 5 shows an exemplary embodiment of an inductive angle sensor 1000 according to the through-shaft principle. The rotatable shaft 200 may extend both through the stator package 10 and through the rotor package 100 and also optionally through the component board 300. In this case, the component board 300, including the excitation coil 40 provided therein, may in each case comprise a through-opening 25, through which the rotatable shaft 200 extends.

The through-opening 25 may have a slightly greater diameter than the rotatable shaft 200, so that the shaft 200 can rotate within the through-opening 25. That is to say that the stator package 10 and the component board 300 may have between the shaft 200 and the through-opening a radial air gap 27, which prevents direct contact between the shaft 200 and the stator package 10 or between the shaft 200 and the component board 300.

The rotor package 100 may also have a through-opening 25, the diameter of which may be slightly greater than the diameter of the shaft 200. The rotor package 100 may be mounted on the shaft 200 for conjoint rotation. For example, the rotor package 100 may be adhesively attached onto the shaft 200 by means of an adhesive 26. Consequently, the rotor package 100 rotates together with the shaft 200, while the shaft 200 rotates in the stationary stator package 10.

The stator package 10 and the rotor package 100 are preferably always contactless. Furthermore, the stator package 10 may advantageously be aligned such that it is centered in relation to the axis of rotation 121 of the rotatable shaft 120. In the end-of-shaft configuration (FIG. 4), the rotor package 100 may be adhesively attached on the end face of a shaft end and the stator package 10 may be arranged ahead of it at an axial distance of approximately 1 mm to 2 mm. In the through-shaft configuration (FIG. 5), the shaft 120 may for example be “infinitely long”, i.e. the shaft end is not available for the angle sensor 100. Then, the rotor package 100 and the stator package 10 could both have a hole 25, through which the shaft 120 runs. The rotor package 100 may be ring-shaped and fixed on the shaft 120. The stator package 10 may likewise be ring-shaped and arranged away from the rotor package 100 by a distance of 1 mm to 2 mm.

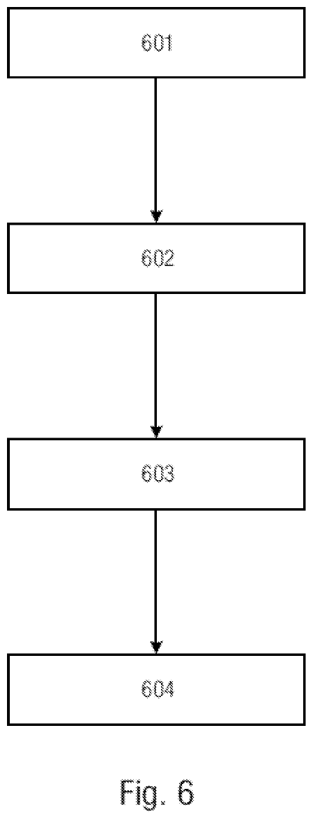

FIG. 6 shows a schematic block diagram to show a method for producing a stator package 10 described here.

In step 601, a substrate 20 is provided and at least two metallization layers 11, 12 arranged at different levels are arranged on the substrate 20.

In step 602, a receiving coil arrangement 30 with at least two electrically conductive receiving coils 31, 32 is produced, designed to receive a magnetic field emitted by an inductive target arrangement 130 that is rotatable in relation to the stator package 10 and to generate induction signals in response thereto.

In step 603, a semiconductor chip 21 is arranged on or alongside the substrate 20 and the semiconductor chip 21 is brought into electrical contact with the receiving coil arrangement 30, wherein the semiconductor chip 21 comprises a circuit which is designed to evaluate the induction signals and to ascertain on the basis of the induction signals a rotation angle between the receiving coils 31, 32 and the inductive target arrangement 130 rotatable in relation thereto.

In step 604, an electrically insulating potting compound 23 is applied, so that it surrounds the substrate 20 including the semiconductor chip 21 and the receiving coils 31, 32.

According to the innovative concept described here, the two receiving coils 31, 32 are implemented in the two metallization layers 11, 12 by thin-film technology when producing the stator package 10.

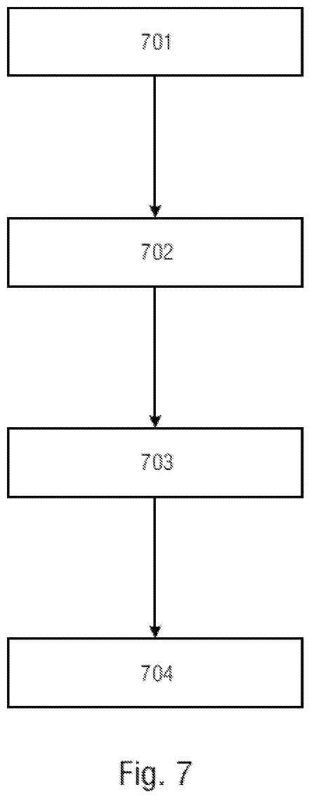

FIG. 7 shows a schematic block diagram to show a method for producing a rotor package 100 described here.

In step 701, a substrate 120 is provided and at least one metallization layer 111 is arranged on the substrate 120.

In step 702, an inductive target arrangement 130 with at least one electrically conductive inductive target 131 is produced, designed to generate an induction current in response to a magnetic field emitted by an excitation coil 40 and to generate a magnetic field corresponding to the induction current and to emit it in the direction of the stator package 10. In this case, the at least one inductive target 131 of the target arrangement 130 is implemented in the at least one metallization layer 111.

In step 703, an electrically insulating sealing or potting compound 123 is applied, so that it surrounds the substrate 120 including the target arrangement 130.

In step 704, the rotor package 100 is arranged on a rotatable shaft 200 for conjoint rotation, so that the rotor package 100 is rotatable in relation to the stator package 10.

The innovative concept described here is to be summarized once again below in other words and its advantages specified.

One aim of the concept described here is to produce a stator package 10 with a size of approximately 5 mm to 15 mm, preferably of less than 10 mm, which comprises a chip 21 with a circuit and receiving coils 31, 32 (and optionally also with an excitation coil 40). Another aim of the concept described here is to produce a rotor package 100 with a size of approximately 5 mm to 15 mm, preferably of less than 10 mm, which comprises a target arrangement 130 with one or more inductive targets 131. The inductive target 131 may be for example a simple conducting component or a planar coil within each case n-fold symmetry (with n>1, i.e. with at least two radial projections with 360°/n symmetry).

No high currents are induced in the receiving coils 31, 32. For this reason, the receiving coils 31, 32 can have very small line dimensions without making any significant sacrifices in terms of signal quality. Only the impedance may slightly suffer as a result. However, this can be counteracted by the effective bandwidth of the sensor. Parasitic effects such as leakage currents, electrostatic discharges and inductances at the coils or at the connections between the coils and the semiconductor chip are less critical.

The production of the coils 31, 32 by thin-film technology allows the high-precision production process of the receiving coils 31, 32 to be kept fully under control. The application of thin-film technology allows better control over the purity of the materials to be used and the process parameters, which in turn leads to increased reliability in the production of the coils 31, 32 in comparison with conventional PCB technologies. An end-of-line test can be carried out on the complete subsystem comprising the chip 21 and the receiving coils 31, 32. In addition, the coils 31, 32 can be surrounded by the potting compound 23, which reliably protects the coils 31, 32 from external influences. For these reasons, the coils 31, 32 do not require resistances in order to carry out integrity checks while operation is in progress, which in turn increases the accuracy and reduces the production costs. The individual metallization layers 11, 12 are aligned better in relation to one another than in PCB technology. The more exact geometry of the coils 31, 32 improves the accuracy and reduces process variation. The smaller overall size of the stator package 10 reduces the inductances as a whole.

The coils 31, 32 may be arranged on one and the same side of the substrate 20 and can be stacked one above the other. This leads to highly precise alignment. The stator package 10 may be arranged in such a way that the coils 31, 32 provided in it face in the direction of the rotor package 100, or that the coils 31, 32 face away from the rotor package 100. The last-mentioned arrangement does increase the vertical distance between the receiving coils 31, 32 in the stator package 10 and the target arrangement in the rotor package 100. However, as a result the dependability and robustness of the angle sensor 1000 can be increased, since the risk of collision is reduced.

In the case of PCBs, an increased number of metallization layers leads to splaying of the substrate. This is not the case in the concept described here, for which reason the provision of a much greater number of metallization layers is conceivable. Consequently, for example, redundant coils and electrostatic shields could be produced, which would be much more difficult to put into practice in PCB technology.

In spite of the relatively small size of the receiving coils 31, 32, with an outside diameter of for example 12 mm, it is possible to provide a hole 25 with a diameter of approximately 2 mm to 4 mm, through which a rotatable shaft 200 can be led. Even if the coils 31, 32 are produced on a silicon substrate 20, such a hole 25 could be made in the silicon. In this respect, it would be advantageous to produce the silicon substrate 20 thinner than usual. The starting thickness of a wafer is approximately 750 μm, and the wafer is often thinned back to 220 μm. In order to produce the hole 25 mentioned at the beginning, it would be conceivable to thin back the substrate 20 to 50 μm. This would allow a passing-through shaft 200 with a diameter of approximately 2-3 mm to be received.

If the substrate 20 is a silicon substrate, it can be produced in an inexpensive semiconductor process, wherein for example only two metallization layers 11, 12 are applied to a raw wafer with a coarse resolution of for example approximately 1 μm to approximately 2 μm and an insulating layer 13 arranged in between and also optionally a final passivation layer. This would be much less expensive than usual, expensive semiconductor processes with a resolution of 125 nm, in which around 20 to 35 layers are applied for the circuit.

For the reasons stated further above, it may be advantageous for the production of receiving coils 31, 32 with an outside diameter of less than 15 mm to apply a production technology that is more intricate than PCB technology. The production of the receiving coils 31, 32 by thin-film technology that is described here may for example envisage using for example the metal layers in the redistribution layer of a wafer level package, for example of an (e)WLB package, or else applying microelectronic production techniques, wherein the receiving coils 31, 32 are for example produced in the metallization layers of inorganic substrates, such as for example glass, ceramic or silicon, for example by the same techniques as for producing connections in microelectronic circuits. Both technologies allow lines and vias in the size range of 10 μm or less (in comparison with vias over 100 μm thick in the case of PCB technology).

The previously mentioned (e)WLB packages are susceptible to mechanical stress exerted on the solder balls, in particular if the package is larger than 15×15 mm and the temperature profile is challenging. In such a case, it would be conceivable to lead electrical connections only to a few solder balls in a small region, i.e. other solder balls would nevertheless continue to be present but could then only serve for mechanical support, i.e. they would not be used for electrical contacts and could also not be soldered on solder points on a component board 300 (they would only be present to prevent tilting of the stator package 10 before soldering on).

The excitation coil 40 could also be provided within the stator package 10, for example on the same substrate 20 (for example a silicon substrate in the case of (e)WLB packages) as the receiving coils 31, 32. The production of the excitation coil 40 is less tricky. Often, just a few turns of wire around the receiving coils 31, 32 are sufficient for this. Furthermore, the wire of the excitation coil 40 is usually thicker than the wire of the receiving coils 31, 32. It is therefore possible to implement the excitation coil 40 (or else multiple excitation coils) on the component board 300, on which the stator package 10 can also be arranged (see FIGS. 4 and 5). This offers the advantage of an easy kind of implementation. On the other hand, it may be advantageous to integrate the excitation coil(s) 40 into the stator package 10. This offers the advantage of fewer statistical outliers with respect to (capacitive and/or inductive) cross coupling between the excitation coil 40 and the receiving coils 31, 32 and offers the possibility of increasing the reliability of the process in the production of the excitation coil 40.

It would also be conceivable to add further discrete electronic components to the stator package 10. For example, the inductive angle sensor 1000 may be extended by adding a capacitor, in order to operate the excitation coil 40 in a resonating manner. It would in this case for example be less expensive to integrate the capacitor into the stator package 10 (for example into an (e)WLB package). If the inductive target 130 were designed as a coil, a series capacitance could be added, in order to operate the target 130 in a resonating manner. If the receiving coils 31, 32 have n-fold symmetry, it would be advantageous if the target 130 also had the same n-fold symmetry.

As mentioned further above, the rotor package 100 may have essentially the form of a pill. The approximately pill-shaped rotor package 100 may have a diameter of approximately 6 mm bis 12 mm and be fixed on the rotatable shaft 200.

With the concept described here, various types of inductive angle sensors 1000 can be produced. The at least two receiving coils 31, 32 may be designed for two-phase angle sensors 1000 for example as sine and cosine coils. In the case of three-phase angle sensors 1000, at least three receiving coils 31, 32 may be provided, for example u-, v- and w coils. For example, it is also possible for multiple receiving coil arrangements each with two or more receiving coils to be provided. For example, the stator package 10 may comprise two receiving coil arrangements, wherein the receiving coils of a first receiving coil arrangement may have n-fold symmetry and the receiving coils of a second receiving coil arrangement may have m-fold symmetry, for example with n=1, m>>1, (for example 11), or with n>>1 (for example 11) and m=n+1. A combination of the signals of the two receiving coil arrangements can produce an angle measurement result that is definite over an angular rotation of the full 360°. By contrast with this, angle sensors 1000 with a single receiving coil arrangement with n-fold symmetry can produce angle measurement results that are definite at least over 360°/n. However, it is also possible for reasons of redundancy to revert to two receiving coil arrangements.

Both the substrate 20 in the stator package 10 and the substrate 120 in the rotor package 100 may be for example a glass substrate with a thickness of 500 μm to 750 μm (for example Borofloat). The metallization layers 11, 12 may for example be applied to the substrate 20 by means of titanium metallization and be structured by means of radio-frequency etching. Oxide or nitride insulating layers may be arranged between the metallization layers 11, 12. In the rotor substrate 120, a target arrangement 130 with one or two inductive targets may for example be implemented in two metallization layers.

The rotor package 100 may for example have an essentially round or oval form. The stator substrate 20 may preferably be rectangular and two or four receiving coils, and optionally one excitation coil, may be implemented in two or four metallization layers.

Depending on the embodiment (through-shaft or end-of-shaft), optionally a centrally arranged hole 25, through which the rotatable shaft 200 can be led, may be provided in the stator package 10 and/or the rotor package 100. The semiconductor chip 21 may be arranged on the stator substrate 20 and be electrically connected to the receiving coils, and also to the excitation coil. Both the stator package 10 and the rotor package 100 may in each case be potted by means of a potting compound 23, 123. On those sides of the packages 10, 100 that lie opposite during operation, corresponding markings may be provided on the potting compound.

The exemplary embodiments described above merely represent an illustration of the principles of the present concept. It goes without saying that modifications and variations of the arrangements and details described here will be apparent to others skilled in the art. It is therefore intended that the concept described here should only be restricted by the scope of protection of the following patent claims and not by the specific details that have been presented here on the basis of the description and the explanation of the exemplary embodiments.

Although some aspects have been described in connection with a device, it goes without saying that these aspects also represent a description of the corresponding method, so that a block or a component of a device can also be understood as meaning a corresponding method step or a feature of a method step. By analogy, aspects which have been described in connection with a method step or as a method step also represent a description of a corresponding block or detail or feature of a corresponding device.

1. A stator package for use in an inductive angle sensor, wherein the stator package comprises:
a substrate, on which at least two metallization layers arranged at different levels are arranged;
a receiving coil arrangement with at least two electrically conductive receiving coils, wherein the receiving coil arrangement is configured to receive a magnetic field emitted by an inductive target arrangement that is rotatable in relation to the stator package and to generate induction signals in response thereto;
a semiconductor chip, which is connected in an electrically conducting manner to the receiving coil arrangement, wherein the semiconductor chip comprises an integrated circuit which is configured to evaluate the induction signals and to ascertain on the basis of the induction signals a rotation angle between the receiving coil arrangement and the inductive target arrangement rotatable in relation thereto; and
an electrically insulating potting compound, which surrounds the substrate including the semiconductor chip and the at least two electrically conductive receiving coils,
wherein the at least two electrically conductive receiving coils are implemented in the at least two metallization layers.

2. The stator package as claimed in claim 1, wherein the stator package is configured without a circuit board.

3. The stator package as claimed in claim 1,
wherein the substrate comprises at least one inorganic material from the group comprising silicon, glass, or ceramic, or is produced from an inorganic material from the group comprising silicon, glass, or ceramic.

4. The stator package as claimed in claim 1,
wherein a surface area circumscribed by the receiving coil arrangement is at least three times greater than a surface area circumscribed by the semiconductor chip, and wherein an outside diameter of the receiving coil arrangement is less than or equal to 16 mm.

5. The stator package as claimed in claim 1,
wherein, a plan view, at least one of the at least two electrically conductive receiving coils of the receiving coil arrangement is arranged around the semiconductor chip, or wherein the semiconductor chip is offset laterally in relation to the receiving coil arrangement.

6. The stator package as claimed in claim 1, further comprising:
electrically conductive plated-through holes with a diameter of less than 10 μm are formed between the at least two metallization layers,
wherein the receiving coil arrangement is configured as ring-shaped, and wherein the electrically conductive plated-through holes are arranged along the inside diameter of the ring-shaped receiving coil arrangement.

7. The stator package as claimed in claim 1, further comprising:
a through-opening, extending through the substrate; and
a shaft, which extends rotatably through the through-opening in the substrate and through the entire stator package, wherein the receiving coil arrangement is arranged in a ring-shaped manner around the through-opening in the substrate and around the shaft.

8. The stator package as claimed in claim 1,
wherein the receiving coil arrangement is arranged on the same side of the substrate as the semiconductor chip, and/or wherein the at least two electrically conductive receiving coils of the receiving coil arrangement are stacked one above the other on the same side of the substrate.

9. The stator package as claimed in claim 1,
wherein the stator package is configured as a wafer level ball grid array (WLB) package or as an embedded wafer level ball grid array (eWLB) package, and wherein the at least two metallization layers are formed in a redistribution layer of the stator package.

10. The stator package as claimed in claim 1,
wherein the stator package has a footprint of less than 15 mm, or of less than 10 mm.

11. The stator package as claimed in claim 1,
wherein the at least two metallization layers have a layer thickness of 100 nm to 5 μm, and/or wherein the at least two electrically conductive receiving coils of the receiving coil arrangement comprise one or more turns with a width of 10 μm or less.

12. The stator package as claimed in claim 1,
wherein the substrate has a thickness of between 50 μm and 800 μm, or between 200 μm and 500 μm.

13. The stator package as claimed in claim 1, further comprising:
a dielectric layer with a layer thickness of 100 nm to 10 μm is arranged between the at least two metallization layers.

14. The stator package as claimed in claim 1,
wherein an excitation coil is formed by thin-film technology in at least one of the at least two metallization layers, or wherein the excitation coil is formed by thin-film technology in at least one third metallization layer arranged on the substrate, and
wherein the excitation coil is connected in an electrically conducting manner to the semiconductor chip and is configured to be induced by an alternating current to generate the magnetic field.

15. The stator package as claimed in claim 1,
wherein the stator package is arranged on a component board which is separate from the substrate and comprises an excitation coil, and
wherein the stator package has a terminal region, by means of which the semiconductor chip arranged in the stator package is connected to the excitation coil.

16. A rotor package for use in an inductive angle sensor together with a stator package, wherein the rotor package comprises:
a substrate, on which at least one metallization layer is arranged;
an inductive target arrangement with at least one electrically conductive inductive target, which is configured to generate an induction current in response to a magnetic field emitted by an excitation coil and to generate a magnetic field corresponding to the induction current and to emit it in the direction of the stator package; and
an electrically insulating sealing or potting compound, which surrounds the substrate including the inductive target arrangement,
wherein the rotor package is arranged on a shaft for conjoint rotation and is rotatable in relation to the stator package, and
wherein the at least one electrically conductive inductive target of the inductive target arrangement is implemented in the at least one metallization layer.

17. An inductive angle sensor, comprising:
a stator package; and
a rotor package,
wherein the stator package comprises:
a substrate on which at least two metallization layers arranged at different levels are arranged;
a receiving coil arrangement with at least two electrically conductive receiving coils, wherein the receiving coil arrangement is configured to receive a magnetic field emitted by an inductive target arrangement that is rotatable in relation to the stator package and to generate induction signals in response thereto;
a semiconductor chip, which is connected in an electrically conducting manner to the receiving coil arrangement, wherein the semiconductor chip comprises an integrated circuit which is configured to evaluate the induction signals and to ascertain on the basis of the induction signals a rotation angle between the receiving coil arrangement and the inductive target arrangement rotatable in relation thereto; and
an electrically insulating potting compound, which surrounds the substrate including the semiconductor chip and the at least two electrically conductive receiving coils,
wherein the at least two electrically conductive receiving coils are implemented in the at least two metallization layers,
wherein the rotor package comprises:
a substrate on which at least one metallization layer is arranged;
an inductive target arrangement with at least one electrically conductive inductive target, which is configured to generate an induction current in response to a magnetic field emitted by an excitation coil and to generate a magnetic field corresponding to the induction current and to emit it in the direction of the stator package; and
an electrically insulating sealing or potting compound, which surrounds the substrate including the inductive target arrangement,
wherein the rotor package is arranged on a shaft for conjoint rotation and is rotatable in relation to the stator package, and
wherein the at least one electrically conductive inductive target of the inductive target arrangement is implemented in the at least one metallization layer.

18. The inductive angle sensor as claimed in claim 17, further comprising:
rotatable shaft,
wherein the rotatable shaft extends through the stator package and is rotatable in relation to the stator package, and
wherein the rotor package is arranged for conjoint rotation on a portion of the rotatable shaft extending out of the stator package.

19. A method for producing a stator package, the method comprising:
providing a substrate and arranging at least two metallization layers arranged at different levels on the substrate;
producing a receiving coil arrangement with at least two electrically conductive receiving coils, wherein the receiving coil arrangement is configured to receive a magnetic field emitted by an inductive target arrangement that is rotatable in relation to the stator package and to generate induction signals in response thereto;
arranging a semiconductor chip on or alongside the substrate and bringing the semiconductor chip into electrical contact with the receiving coil arrangement, wherein the semiconductor chip comprises a circuit which is configured to evaluate the induction signals and to ascertain on the basis of the induction signals a rotation angle between the receiving coil arrangement and the inductive target arrangement rotatable in relation thereto; and
applying an electrically insulating potting compound, which surrounds the substrate including the semiconductor chip and the receiving coil arrangement,
wherein the at least two electrically conductive receiving coils of the receiving coil arrangement are implemented in the at least two metallization layers by thin-film technology.

20. A method for producing a rotor package for use together with a stator package in an inductive angle sensor, wherein the method comprises the following steps:
providing a substrate and arranging at least one metallization layer on the substrate;
producing an inductive target arrangement with at least one electrically conductive inductive target, which is configured to generate an induction current in response to a magnetic field emitted by an excitation coil and to generate a magnetic field corresponding to the induction current and to emit it in the direction of the stator package;
wherein the at least one inductive target of the target arrangement is implemented in the at least one metallization layer;
applying an electrically insulating sealing or potting compound, which surrounds the substrate including the inductive target arrangement; and
arranging the rotor package on a rotatable shaft for conjoint rotation, so that the rotor package is rotatable in relation to the stator package.
